(19) United States
(12) Patent Application Publication
(10) Pub. No.: US 2013/0134964 A1
(43) Pub. Date: May 30, 2013

(54) COIL COMPRISING A WINDING COMPRISING A MULTI-AXIAL CABLE

(71) Applicants: Fredrik Ahrentorp, Goteborg (SE); Jakob Blomgren, Kungalv (SE); Christian Jonasson, Landvetter (SE); Andrea Prieto-Astalan, Onsala (SE); Christer Johansson, Goteborg (SE)

(72) Inventors: Fredrik Ahrentorp, Goteborg (SE); Jakob Blomgren, Kungalv (SE); Christian Jonasson, Landvetter (SE); Andrea Prieto-Astalan, Onsala (SE); Christer Johansson, Goteborg (SE)

(73) Assignee: IMEGO AB, Goteborg (SE)

(21) Appl. No.: 13/699,079

(22) PCT Filed: May 20, 2011
(86) PCT No.: PCT/SE2011/050636

§ 371 Date: Feb. 1, 2013

(30) Foreign Application Priority Data
May 26, 2010 (SE) 1050526-1

(51) Int. Cl. G01R 33/16; G01R 35/00; H01F 5/00

(52) U.S. Cl. CPC G01R 33/16; H01F 5/00; G01R 35/00
USPC 324/201; 336/195; 324/601

(57) ABSTRACT

The present invention relates to a coil comprising a winding (45). The winding comprises a multi-axial cable with one shielding layer connected to ground.

### TECHNICAL FIELD

The present invention relates to coils in general and measurement coils in particular.

### BACKGROUND OF THE INVENTION

Dynamic magnetic properties of a material can be measured by sweeping the frequency of the measuring field and measure the magnetic response, i.e. (real and imaginary components of the AC susceptibility).

WO 2007120095, for example, by the same applicant describes a device for detecting a magnetic response or changes in a magnetic response of at least one magnetic particle in a carrier fluid. The detection principle comprises measuring the magnetic particles characteristic rotation period, and the measurement involves measurement of a Brownian relaxation in the carrier fluid under influence of an external pulsed magnetic field. The device comprises an arrangement for generating the pulsed magnetic field and at least two substantially identical detection coils connected in gradiometer coupling to detection electronics for measuring the frequency.

When measuring the dynamic magnetic properties of a material, induction coil techniques are often used. In this case the AC susceptometer is based on the principle of induction, and consist of an excitation coil providing an alternating homogenous magnetic field around a detection coil system placed inside the excitation coil.

A detection coil system in the form of a first order gradiometer coupling placed in the center of the excitation coil 110 is shown in FIG. 1. The detection coil system 100 is formed by positioning two well matched coils 120 and 130 with their length axis co-linear to the length axis of the excitation coil and coupled together so that the detection coil system detects the rate of the magnetic flux difference between the two coils.

### SUMMARY OF THE INVENTION

In AC-susceptometry, it is often necessary to measure up to frequencies of several MHz to adequately establish the magnetic properties of a sample. This application describes methods and components used for coil system of a high-frequency susceptometer (HF-AC susceptometer) of maximum measurement frequency up to 100 MHz, preferably at least 10 MHz.

Thus, the invention relates a coil comprising a carrier and a winding. The winding comprises a multi-axial cable with one shielding layer connected to ground. The multi-axial cable may be coaxial or triaxial. Preferably, according to one embodiment, the coil is an excitation coil and/or detection coil in a coil system for susceptometry. The coil may operate in a frequency to 100 MHz, at least 10 MHz. In one embodiment, a second shielding layer of the cable is connected to a current source voltage. According to one embodiment, one or several shielding layers of the multi-axial cable is divided in several sections, with each section directly connected to the ground.

The invention also relates to a device for detecting a dynamic magnetic response or changes in a dynamic magnetic response of a general magnetic material or at least one magnetic particle in a carrier fluid. The detection comprises measuring the magnetic particles characteristic magnetic relaxation in the carrier fluid under influence of an external magnetic field. The device comprises means for generating the magnetic field, at least two substantially identical detection coils connected in a gradiometer coupling to detection electronics for measuring the induced voltage that is dependent on the dynamic magnetic properties of a sample in the detection coils. The excitation coil and and/or at least one of detection coils comprise a winding and the winding comprises a multi-axial cable with one shielding layer connected to ground. The multi-axial cable may be coaxial or triaxial. The device may operate in a frequency up to 100 MHz, at least 10 MHz. The second shielding layer may be connected to a current source voltage. The field may be sinusoidal magnetic field or a pulsed magnetic field.

The invention also relates to method of calibrating a device as described earlier. The method comprising: a first step of measuring the system response with an empty sample holder, a second step of computing difference in signal when the empty sample holder is in the first coil to when the sample holder is in the second coil, a third step of measuring the system with a sample containing a material with a known and preferably frequency independent AC magnetic susceptibility; calibrating the system based on said measurements with respect to the amplitude and phase changes due to the device.

The invention also relates to method of calibrating a device as described earlier. The method comprising: measuring a signal with an excitation voltage applied, but no excitation current present, as a background signal, subtracting said measured signal from a measurement signal to remove capacitive contributions to derive magnetic properties of the sample, and calibrating with respect to amplitude and phase changes due to device.

### BRIEF DESCRIPTION OF THE DRAWINGS

In the following, the invention will be described with reference to enclosed non-limiting exemplary drawings, in which:

FIG. 1 is a schematic of a known excitation and detection coil system.

FIG. 2 is a cut through a coaxial cable,

FIG. 3 is a cut through a traxial cable, and

FIG. 4 is a schematic coil system according to the invention.

### DETAILED DESCRIPTION OF PREFERRED EMBODIMENTS

In coil design (excitation and detection coils as mentioned earlier), e.g. for AC susceptometer applications, the parasitic capacitance of individual windings of the coil must be taken into account. This capacitance, together with the coil inductance and resistance, determines the coil resonance frequency above which the inductive response decreases rapidly, thus the resonance frequency should preferably be higher than the maximum measurement frequency. The resonance frequency can be increased by
Decreasing the number of windings
Increasing the space between windings
Decreasing dielectric constant of the insulating material between the windings

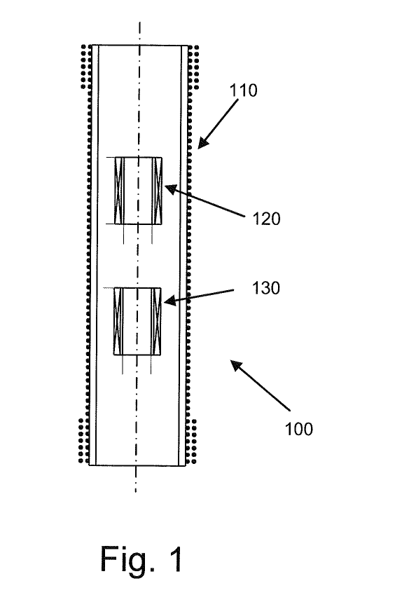

For each coil of the coil system of FIG. 1, the resonance frequency should be above the maximum measurement frequency of the AC susceptometer. However, there may still be resonances below the measurement frequency in the coil system due to parasitic capacitances between the excitation coil and detection coils. Furthermore, the balance of the two detection coils is affected by the dielectric properties of the sample being measured through the parasitic capacitance between detection coils.

According to the invention, in order to reduce the parasitic capacitances, low capacitance coaxial or multi-axial cable can be used as coil windings of the detection and/or excitation coil with its shield grounded at one end.

A multi-axial cable in this context relates to a cable with a core conductor and one or several (>1) conductive shielding layers.

In one embodiment, the shield(s) of the multi-axial cable can be divided in multiple sections, with each section directly connected to the ground point in order to reduce the inductance of the shield-to-ground path.

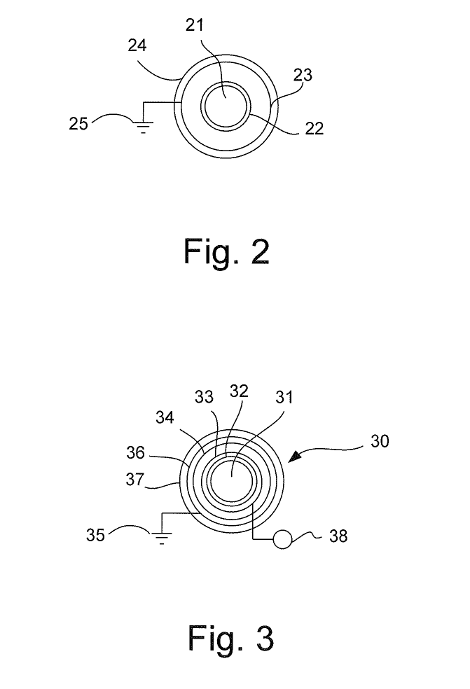

FIG. 2 illustrates a cut through a coaxial cable 20 comprising a core 21 of a conducting material, an insulating layer 22, a conducting shielding layer 23 and an outer insulating layer 24. According to the invention the conducting shielding layer 23 is connected to ground 25.

FIG. 3 illustrates a cut through a triaxial cable 30 comprising a core 31 of a conducting material, an insulating layer 32, a conducting shielding layer 33, another insulating layer 34, a second conducting shielding layer 36 and an outer insulating layer 37. According to the invention, the excitation coil can be wound using triaxial cable with one end of the outer shield 36 connected to the signal ground 35, and one end of the inner shield 33 connected to the excitation current source voltage (guard) 38.

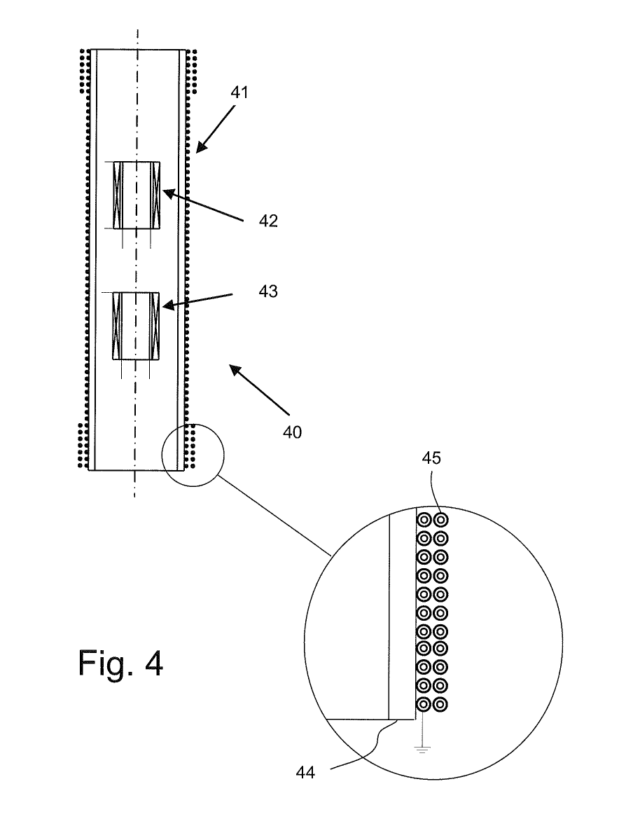

FIG. 4 illustrates an embodiment of detection coil system 40, e.g. in accordance with above mentioned WO 2007120095, but adapted to the present invention, in the form of a first order gradiometer coupling placed in the center of the excitation coil 41. The detection coil system 40 is formed by positioning two well matched coils 42 and 43 with their length axis co-linear to the length axis of the excitation coil 41 and coupled together so that the detection coil system may detect the rate of the magnetic flux difference between the two coils.

A portion of the excitation coil is illustrated enlarged (encircled area). In this case, the excitation coil 41 comprises a tubular housing 44 provided with a winding comprising coaxial cable 45. At one end the shielding of the coaxial cable is connected to signal ground.

The detection coils 42 and 43 may also be provided with same type of windings as the excitation coil 41. However, a mixture of, for example coaxial and triaxial cables may be used to as winding for separate coils.

Ideally, without sample in the detection coils, the signal picked up from the detection coils should be zero if the detection coils are perfectly balanced. Nevertheless, there may still be an electrically coupled signal from excitation coil to detection coil present, even if coaxial cable has been used in all coils. In the embodiment of the HF AC susceptometer, this unwanted signal can first be measured with no excitation current present, as a (capacitive) background signal, which later can be subtracted from measurement signal to derive the magnetic properties of the sample. The HF AC susceptometer is further calibrated with respect to amplitude and phase changes due to the instrument itself. The two calibration procedures, background and amplitude and phase compensation is described below.

In one embodiment, the measurement of the unwanted signal may be done by placing a relay in the excitation coil circuit just before the ground point. The capacitive background is analyzed by measuring the system response with the excitation output voltage on, but with the relay open. In this configuration no current will flow in the excitation coil, but an excitation voltage will be present in the excitation coil. The response picked up by the detection coil gives information on the capacitive background.

In another embodiment, the system for measurements of the AC susceptibility of for instance a magnetic particle system may be calibrated by a two-step procedure:

In the first step, the system response is measured with an empty sample holder. The effect this measurement picks up is the difference in signal when the empty sample holder is in the upper coil to when the sample holder is in the lower coil. The difference is attributed to the dielectric properties of the sample holder and the mechanical arm moving the sample holder. The resulting (complex) voltage, V_{b}=V_{b}^{Re}+j*V_{b}^{lm}, is a background signal which is subtracted from any measured signal in the subsequent measurements. The second step is performed with a sample containing a material with a known and preferably frequency independent magnetic susceptibility, for instance a paramagnetic material such as Dy₂O₃. The calibration materials are chosen preferably to have a frequency independent susceptibility in the frequency range used in our sensor system. The value of the susceptibility of the calibration material should preferably be in the same range as for the measured sample. The geometry and dimensions of the calibration sample should preferably be the same as for the measurement samples, in order to get the correct coupling factor in the detection coil(s). The measured voltage minus the background gives the (complex) voltage-to-susceptibility transfer factor, G=X_{cal}/(V_{cal}−V_{b}).

The frequency dependency of the gain and the phase between the applied excitation field and the magnetic response from the detection coil(s) is a major concern in construction of a high bandwidth susceptometer. The frequency dependency of the gain and the phase becomes strong at high frequencies, especially at frequencies close to the resonance frequency of the detection coil(s) or the excitation coil. The gain and phase can also become frequency dependent due to the properties of the excitation electronics and/or the detection electronics. The measured sample data will become incorrect, especially at high frequencies, if these effects are not compensated for.

The frequency dependency of the gain and the phase shift are compensated by means of a routine similar to the calibration described above. The difference is that the two calibration steps at many different frequencies are performed. Hence, the result is a frequency dependent background (complex) voltage V_{b}(f) and a (complex) frequency dependent voltage-to-susceptibility transfer factor, G(f)=X_{cal}(f)/(V_{cal}(f)−V_{b}(f)) . Using a frequency independent reference sample (a sample with a constant X_{cal}) simplifies the second step in the compensation routine.

In the above description, the invention is described with reference to susceptometer applications. However, the teachings of the invention may easily be employed for coils in other systems such as: magnetometers in which magnetic properties are measured, measuring external magnetic fields in MHz frequency region, e.g. in Magnetic Resonance Imaging (MRI) systems, etc.

The invention is not limited to the described and illustrated embodiments and the teachings of the invention can be varied in a number of ways without departure from the scope of the invention as claimed in the attached claims.

1. A coil comprising a winding, wherein said winding comprises a multi-axial cable with one shielding layer connected to ground.

2. The coil of claim 1, wherein said multi-axial cable is coaxial.

3. The coil of claim 1, wherein said multi-axial cable is triaxial.

4. The coil of claim 1, wherein said coil is an excitation coil in a coil system for susceptometry.

5. The coil of claim 1, wherein said coil is a detection coil in a coil system for susceptometry.

6. The coil of claim 1 for operation in a frequency to 100 MHz, at least 10 MHz.

7. The coil of claim 3, wherein a second shielding layer is connected to a current source voltage.

8. The coil of claim 1, wherein one or several shielding layers of said multi-axial cable is divided in several sections, with each section directly connected to the ground.

9. A device for detecting a dynamic magnetic response or changes in a dynamic magnetic response of a magnetic material or at least one magnetic particle in a carrier fluid, said detection comprising measuring said magnetic particle's characteristic magnetic relaxation in said carrier fluid under influence of an external magnetic field, said device comprising means for generating said magnetic field, at least two substantially identical detection coils connected in a gradiometer coupling to detection electronics for measuring the induced voltage that is dependent on the dynamic magnetic properties of a sample in the detection coils, characterized in that said excitation coil and and/or detection coils comprise a winding and said winding comprises a multi-axial cable with at least one shielding layer connected to ground.

10. The device of claim 9, wherein said multi axial cable is coaxial.

11. The device of claim 9, wherein said multi-axial cable is triaxial.

12. The device of claim 1 for operation in a frequency to 100 MHz, at least 10 MHz.

13. The device of claim 11, wherein a second shielding layer is connected to a current source voltage.

14. The device according to claim 9, wherein said field is sinusoidal magnetic field or a pulsed magnetic field.

15. A method of calibrating a device according to claim 9, the method comprising:
a first step of measuring the system response with an empty sample holder,
a second step of computing difference in signal when the empty sample holder is in the first coil to when the sample holder is in the second coil,
a third step of measuring the system with a sample containing a material with a known and preferably frequency independent magnetic susceptibility;
calibrating the system with respect to amplitude and phase changes due to the device itself.

16. A method of calibrating a device according to claim 9, the method comprising:
measuring a signal with no excitation current present, as a background signal,
subtracting said measured signal from a measurement signal to derive magnetic properties of the sample
calibrating with respect to amplitude and phase changes due to device.
